(19) United States
(12) Patent Application Publication
(10) Pub. No.: US 2020/0137339 A1
(43) Pub. Date: Apr. 30, 2020

(54) IMAGE SENSOR

(71) Applicant: Guangzhou Tyrafos Semiconductor Technologies Co., LTD., Guangzhou (CN)

(72) Inventors: Ping-Hung Yin, Taipei City (TW); Jia-Shyang Wang, Miaoli County (TW)

(73) Assignee: Guangzhou Tyrafos Semiconductor Technologies Co., LTD, Guangzhou (CN)

(21) Appl. No.: 16/660,816

(22) Filed: Oct. 23, 2019

Related U.S. Application Data
(60) Provisional application No. 62/749,683, filed on Oct. 24, 2018.

(51) Int. Cl. H04N 5/378; H01L 27/146; H04N 5/3745

(52) U.S. Cl. CPC H04N 5/378; H04N 5/37452; H01L 27/14643

(57) ABSTRACT

An image sensor including a signal processor and a pixel array is provided. The pixel array includes a plurality of active pixel units and a plurality of reference pixel units. The active pixel units are coupled to the signal processor. The active pixel units are configured to receive an image light signal during an image sensing period to output a plurality of sensing signals. The reference pixel units are coupled to the signal processor. The reference pixel units are masked and do not receive the image light signal during the image sensing period, so as to output a plurality of reference signals. The signal processor is configured to receive the sensing signals and the reference signals. The signal processor performs signal subtraction on the sensing signals and the reference signals to correspondingly generate a plurality of pixel data.

### CROSS-REFERENCE TO RELATED APPLICATION

This application claims the priority benefit of U.S. provisional application Ser. No. 62/749,683, filed on Oct. 24, 2018. The entirety of the above-mentioned patent application is hereby incorporated by reference herein and made a part of this specification.

### BACKGROUND OF THE INVENTION

### Field of the Invention

The invention relates to a sensor, and particularly relates to an image sensor.

### Description of Related Art

In recent years, the image sensing technology has been widely used in various electronic devices to provide various image sensing functions, such as fingerprint sensing and human face sensing. In particular, a CMOS image sensor (CIS) is a common image sensor type at present.

However, a general CIS stores sensing signals output by pixel units in a digital form, so that the general CIS needs to be equipped with a frame buffer. Under the current trend of miniaturization of electronic devices, the CIS equipped with the frame buffer cannot effectively reduce the volume. Based on the above, in terms of how to save the space and cost of an image sensor using a digital frame buffer, the solutions of several embodiments will be presented below.

### SUMMARY OF THE INVENTION

The invention is directed to an image sensor capable of providing a good image sensing function.

The image sensor of the invention includes a signal processor and a pixel array. The pixel array includes a plurality of active pixel units and a plurality of reference pixel units. The active pixel units are coupled to the signal processor. The active pixel units are configured to receive an image light signal during an image sensing period to output a plurality of sensing signals. The reference pixel units are coupled to the signal processor and are masked and do not receive the image light signal during the image sensing period, so as to output a plurality of reference signals. The signal processor is configured to receive the sensing signals and the reference signals and perform subtraction on the sensing signals and the reference signals to correspondingly generate a plurality of pixel data.

Based on the above, the image sensor of the invention can utilize the active pixel units and the reference pixel units having the same leakage current effect to respectively generate the sensing signals and the reference signals, and subtraction is performed on the sensing signals and the reference signals to generate correct pixel data.

To make the features and advantages of the invention clear and easy to understand, the following gives a detailed description of embodiments with reference to accompanying drawings.

### BRIEF DESCRIPTION OF THE DRAWINGS

FIG. 1 is a configuration schematic diagram of an image sensor according to an embodiment of the invention.

FIG. 2 is a functional block diagram of an image sensor according to an embodiment of the invention.

FIG. 3 is a circuit schematic diagram of an active pixel unit according to the embodiment of FIG. 2 of the invention.

FIG. 4 is a circuit schematic diagram of a reference pixel unit according to the embodiment of FIG. 2 of the invention.

FIG. 5 is a signal timing diagram according to the embodiments of FIG. 3 and FIG. 4 of the invention.

### DESCRIPTION OF THE EMBODIMENTS

To make the content of the invention more comprehensible, embodiments are described below as examples according to which the invention can indeed be implemented. Wherever possible, the same reference numbers are used in the drawings and the description to refer to the same or like parts, components or steps.

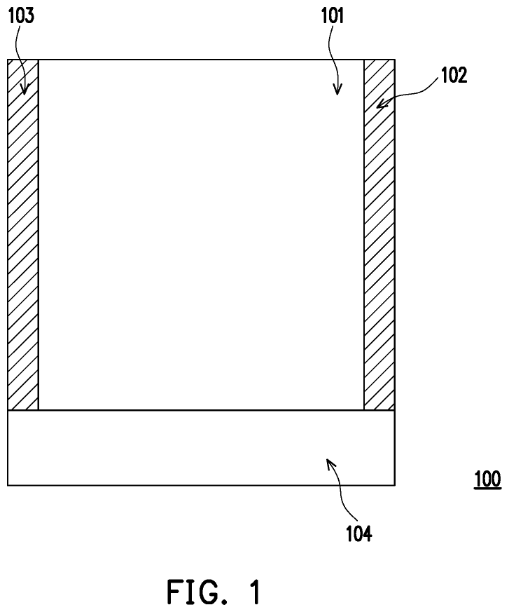

FIG. 1 is a configuration schematic diagram of an image sensor according to an embodiment of the invention. Referring to FIG. 1, the configuration of an image sensor 100 is as shown in FIG. 1. The image sensor 100 may be a CMOS image sensor (CIS). The image sensor 100 includes an active region 101, peripheral regions 102 and 103 and a circuit layout region 104. A plurality of pixel units of the pixel array of the image sensor 100 can be disposed in the active region 101 and the peripheral regions 102 and 103. In the present embodiment, the active region 101 includes a plurality of active pixel units arranged in an array and configured to receive an image light signal during an image sensing period. The peripheral regions 102 and 103 include one reference pixel unit or a plurality of reference pixel units arranged in an array, and sensing regions of the reference pixel units of the peripheral regions 102 and 103 may be covered with a metal layer, for example. That is, because the reference pixel units of the peripheral regions 102 and 103 are masked, the reference pixel units of the peripheral regions 102 and 103 do not receive the image light signal during the image sensing period, but output reference signals in line with the operation of the active pixel units of the active region 101. Furthermore, the circuit layout region 104 may be provided with an associated readout circuit or signal processor such as a digital to analog converter (DAC), but the invention is not limited thereto. Furthermore, the peripheral regions provided with the reference pixel units in the invention are not limited to the positions as shown in FIG. 1. In an embodiment, the peripheral regions provided with the reference pixel units may also be positioned between the active region 101 and the circuit layout region 104. Furthermore, in another embodiment, the image sensor 100 may be a fingerprint sensor.

Specifically, in the present embodiment, each column of the pixel array of the image sensor 100 may include a plurality of active pixel units positioned in the active region 101 and one or more reference pixel units positioned in the peripheral regions 102 and 103 at two sides of the active region 101. It should be noted that the active pixel units receive the image light signal during the image sensing period to output the sensing signals. The reference pixel units are masked and do not receive the image light signal during the image sensing period, but the reference pixel units still perform a sensing operation simultaneously with the active pixel units to output the reference signals. Furthermore, the active pixel units and the reference pixel units of the present embodiment store the sensing signals and the reference signals by utilizing respective charge storage components. In other words, in the present embodiment, the sensing signals and the reference signals are stored in an analog form to effectively save the space and cost of the image sensor 100 using a digital frame buffer.

It should be noted that in the present embodiment, the pixel array of the image sensor 100 is configured to perform a global shutter operation during the image sensing period to simultaneously expose all active pixel units of the pixel array, but the invention is not limited thereto. In an embodiment, the pixel array of the image sensor 100 is configured to perform a rolling shutter operation during the image sensing period to simultaneously expose each column of the active pixel units of the pixel array, and a plurality of columns of the pixel array are sequentially exposed.

In addition, in some embodiments of the invention, the image sensor 100 is coupled to a main control circuit at another end (e.g., a processor of a mobile phone) through a serial peripheral interface (SPI). That is, the image sensor 100 determines, according to a data transmission request of the serial peripheral interface, whether to read out the sensing signals of the active pixel units and the reference signals of the reference pixel units in one of a plurality of columns of the pixel array. However, based on the data transmission characteristics of the serial peripheral interface, the overall image data of the same sensing image may be transmitted from the image sensor 100 to the main control circuit at the other end in a continuous or discontinuous mode.

That is, each column of pixel data of the pixel array of the image sensor 100 may be read out respectively by the signal processor at different and discontinuous times. Because the charge storage component for storing the sensing signals or the reference signals in each pixel unit may have a leakage current effect, in the present embodiment, subtraction is performed on the sensing signals and the reference signals respectively provided by the charge storage components of the active pixel units and the charge storage components of the reference pixel units having the same leakage current effect, so as to reduce or eliminate the influence of signal distortion caused by the leakage current effect. Therefore, the image sensor 100 of the present embodiment can generate correct pixel data.

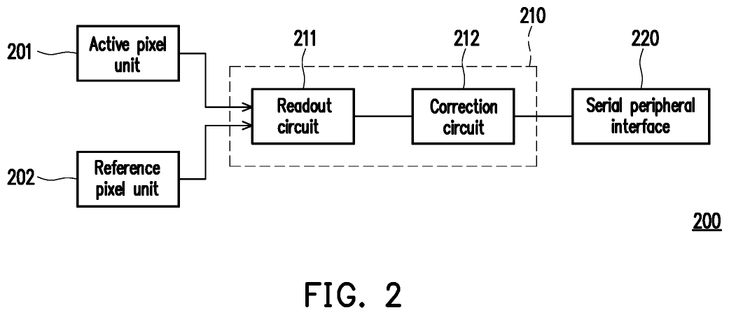

FIG. 2 is a functional block diagram of an image sensor according to an embodiment of a reference pixel unit of the invention. Referring to FIG. 2, in the present embodiment, an active pixel unit in the pixel array and a corresponding reference pixel unit are configured to explain an image sensing operation of the invention. In the present embodiment, an image sensor 200 includes a signal processor 210 and a serial peripheral interface 220. In the present embodiment, the signal processor 210 includes a readout circuit 211 and a correction circuit 212. The readout circuit 211 is coupled to an active pixel unit 201 and a reference pixel unit 202. The readout circuit 211 is configured to simultaneously read out a sensing signal of the active pixel unit 201 and a reference signal of the reference pixel unit 202 at a data readout time point, and provide the sensing signal and the reference signal to the correction circuit 212. In the present embodiment, the correction circuit 212 may include a plurality of logic operation circuits and can perform a signal subtraction operation on the sensing signal and the reference signal to output pixel data to the serial peripheral interface 220.

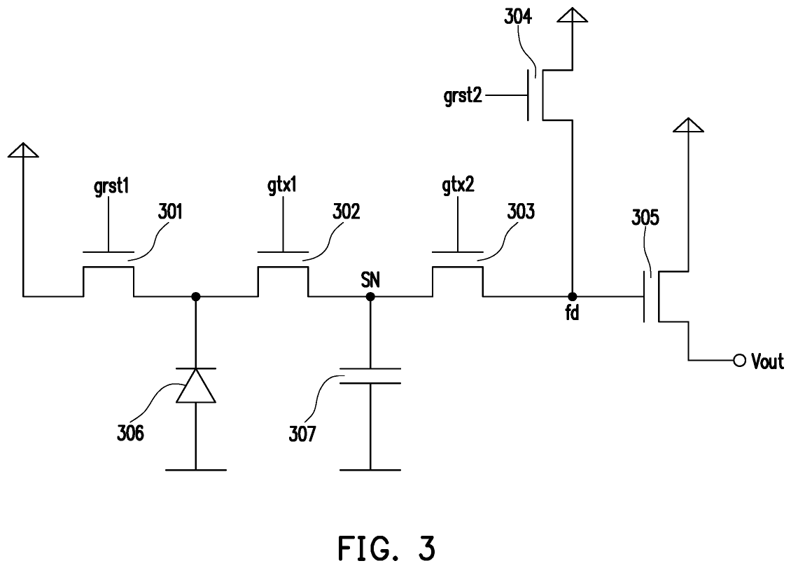

FIG. 3 is a circuit schematic diagram of an active pixel unit according to the embodiment of FIG. 2 of the invention. Referring to FIG. 2 and FIG. 3, the active pixel unit 201 includes a circuit framework as shown in FIG. 3, and the active pixel unit 201 may include switches 301-305, a photodiode 306 and a charge storage component 307. The charge storage component 307 is an analog charge storage component and may be a capacitor unit. The switches 301-305 may be transistor switches. In the present embodiment, a first terminal of the switch 301 is coupled to a reference voltage (or system voltage). A control terminal of the switch 301 receives a control signal grst1. A first terminal of the photodiode 306 is coupled to a second terminal of the switch 301. A second terminal of the photodiode 306 is grounded. A first terminal of the switch 302 is coupled to the second terminal of the switch 301 and the first terminal of the photodiode 306. A control terminal of the switch 302 receives a control signal gtx1. A first terminal of the charge storage component 307 is coupled to a second terminal of the switch 302. A second terminal of the charge storage component 307 is grounded. A first terminal of the switch 303 is coupled to the second terminal of the switch 302 and the first terminal of the charge storage component 307. A second terminal of the switch 303 is coupled to a floating diffusion node fd. A control terminal of the switch 303 receives a control signal gtx2. A first terminal of the switch 304 is coupled to the reference voltage (or system voltage). A second terminal of the switch 304 is coupled to the floating diffusion node fd. A control terminal of the switch 304 receives a control signal grst2. A first terminal of the switch 305 is coupled to the reference voltage (or system voltage). A control terminal of the switch 305 is coupled to the floating diffusion node fd. A second terminal of the switch 305 is coupled to a data output terminal Vout, and the data output terminal Vout is coupled to the readout circuit 211 of the signal processor 210.

In the present embodiment, before the image sensing period (exposure period or integration period), the switch 301 of the active pixel unit 201 is turned on to reset the photodiode 306. Subsequently, during the image sensing period, the switches 301 and 302 of the active pixel unit 201 are turned off, and the photodiode 306 senses an image light signal. Then, at a data storage time point, the switch 302 is turned on, so that the photodiode 306 of the active pixel unit 201 outputs the sensing result of the image light signal as a sensing signal to the charge storage component 307, and the charge storage component 307 stores the sensing signal. Therefore, a node voltage SN of the first terminal of the charge storage component 307 has a voltage corresponding to the sensing signal. Then, at the data readout time point, the switch 303 is turned on, and the switch 304 is turned off, so that the voltage of the floating diffusion node fd corresponds to the sensing signal stored by the charge storage component 307. In other words, the sensing signal stored by the charge storage component 307 is read out through the switch 305 to the data output terminal Vout.

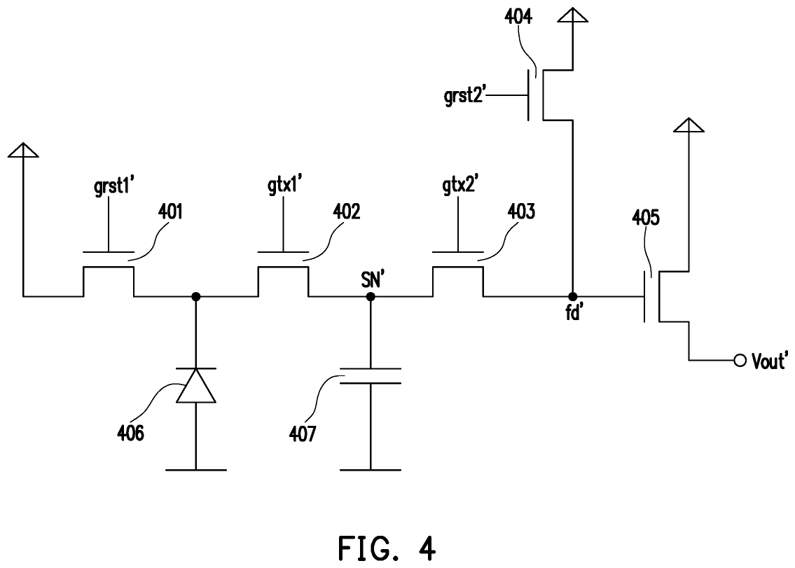

FIG. 4 is a circuit schematic diagram of a reference pixel unit according to the embodiment of FIG. 2 of the invention. Referring to FIG. 2 and FIG. 4, the reference pixel unit 202 includes a circuit framework as shown in FIG. 4, and the reference pixel unit 202 may include switches 401-405, a photodiode 406 and a charge storage component 407. The charge storage component 407 is an analog charge storage component and may be, for example, a capacitor unit. In the present embodiment, a first terminal of the switch 401 is coupled to a reference voltage (or system voltage). A control terminal of the switch 401 receives a control signal grst1′. A first terminal of the photodiode 406 is coupled to a second terminal of the switch 401. A second terminal of the photodiode 406 is grounded. A first terminal of the switch 402 is coupled to the second terminal of the switch 401 and the first terminal of the photodiode 406. A control terminal of the switch 402 receives a control signal gtx1′. A first terminal of the charge storage component 407 is coupled to a second terminal of the switch 402. A second terminal of the charge storage component 407 is grounded. A first terminal of the switch 403 is coupled to the second terminal of the switch 402 and the first terminal of the charge storage component 407. A second terminal of the switch 403 is coupled to a floating diffusion node fd′. A control terminal of the switch 403 receives a control signal gtx2′. A first terminal of the switch 404 is coupled to the reference voltage (or system voltage). A second terminal of the switch 404 is coupled to the floating diffusion node fd'. A control terminal of the switch 404 receives a control signal grst2′. A first terminal of the switch 405 is coupled to the reference voltage (or system voltage). A control terminal of the switch 405 is coupled to the floating diffusion node fd′. A second terminal of the switch 405 is coupled to a data output terminal Vout′, and the data output terminal Vout′ is coupled to the readout circuit 211 of the signal processor 210.

In the present embodiment, before the image sensing period, the switch 401 of the reference pixel unit 202 is turned on to reset the photodiode 406. Subsequently, during the image sensing period, the switches 401 and 402 of the reference pixel unit 202 are turned off, and the photodiode 406 senses an image light signal. Then, at a data storage time point, the switch 402 is turned on, so that the photodiode 406 of the reference pixel unit 202 outputs the sensing result of the image light signal as a sensing signal to the charge storage component 407, and the charge storage component 407 stores the sensing signal. Therefore, a node voltage SN′ of the first terminal of the charge storage component 407 has a voltage corresponding to the sensing signal. Then, at the data readout time point, the switch 403 is turned on, and the switch 404 is turned off, so that the voltage of the floating diffusion node fd′ corresponds to the sensing signal stored by the charge storage component 407. In other words, the sensing signal stored by the charge storage component 407 is read out through the switch 405 to the data output terminal Vout′.

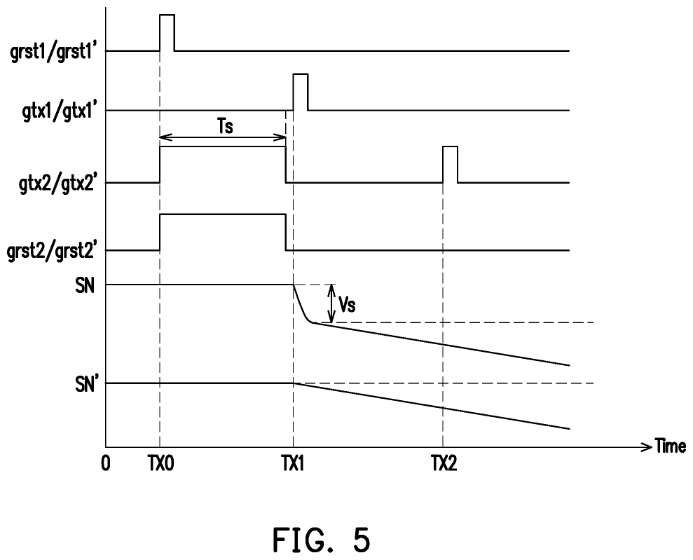

FIG. 5 is a signal timing diagram according to the embodiments of FIG. 3 and FIG. 4 of the invention. Referring to FIG. 3 to FIG. 5, at a time point Tx0, the control signals grst1 and grst1′ are at a high voltage level. The switch 301 of the active pixel unit 201 and the switch 401 of the reference pixel unit 202 are turned on according to the control signals grst1 and grst1′, so that the photodiode 306 of the active pixel unit 201 and the photodiode 406 of the reference pixel unit 202 are discharged through the switches 301 and 401 for resetting. Furthermore, the control signals gtx2, gtx2′, grst2 and grst2′ are at a high voltage level. The switches 303 and 304 of the active pixel unit 201 are turned on, and the switches 403 and 404 of the reference pixel unit 202 are turned on, so that the charge storage component 307 of the active pixel unit 201 and the charge storage component 407 of the reference pixel unit 202 are discharged through the switches 303 and 304 and the switches 403 and 404 for resetting. Therefore, the node voltage SN of the active pixel unit 201 and the node voltage SN′ of the reference pixel unit 202 are maintained at a high voltage level.

Then, when the photodiode 306 of the active pixel unit 201 and the photodiode 406 of the reference pixel unit 202 are simultaneously finished, the control signals gtx1, gtx1′, grst2 and grst2′ are still maintained at a high voltage level, so that the charge storage component 307 of the active pixel unit 201 and the charge storage component 407 of the reference pixel unit 202 are continuously discharged, and the node voltage SN of the active pixel unit 201 and the node voltage SN′ of the reference pixel unit 202 are still maintained at a high voltage level. During an image sensing period Ts, the photodiode 306 of the active pixel unit 201 senses the image light signal, and the photodiode 406 of the reference pixel unit 202 is masked and does not receive the image light signal.

Then, at a time point Txl (data storage time point), the control signals gtx1 and gtx1′ are at a high voltage level. The switch 302 of the active pixel unit 201 and the switch 402 of the reference pixel unit 202 are turned on according to the control signals gtx1 and gtx1′, so that the photodiode 306 of the active pixel unit 201 and the photodiode 406 of the reference pixel unit 202 are discharged to the charge storage components 307 and 407 through the switches 302 and 402, so as to charge the charge storage components 307 and 407. Therefore, the charge storage component 307 stores the sensing signal provided by the photodiode 306. The charge storage component 407 stores the reference signal provided by the photodiode 406. However, based on the influence of the leakage current effect, the voltage level of the charge storage components 307 and 407 gradually decreases between the time Tx1 and the time Tx2. Because the active pixel unit 201 and the reference pixel unit 202 have the same circuit configuration and are positioned in the same row or the same column in the pixel array to couple to the same row signal line or column signal line, the active pixel unit 201 and the reference pixel unit 202 have the same or similar leakage current effect. In other words, the charge storage components 307 and 407 have the same or similar gradual decrease condition. As shown in FIG. 5, the node voltage SN of the active pixel unit 201 and the node voltage SN′ of the reference pixel unit 202 have the same or similar gradual decrease condition.

Finally, at a time point Tx2 (data readout time point), the control signals gtx2 and gtx2′ are at a high voltage level. The switch 303 of the active pixel unit 201 and the switch 403 of the reference pixel unit 202 are turned on according to the control signals gtx2 and gtx2′, so that the floating diffusion node fd of the active pixel unit 201 and the floating diffusion node fd′ of the reference pixel unit 202 are identical to the node voltages SN and SN′. In other words, the data stored in the charge storage components 307 and 407 is read out through the switches 305 and 405 to the data output terminals Vout and Vout′. Therefore, the readout circuit 211 as shown in FIG. 2 can simultaneously read out the sensing signal of the active pixel unit 201 and the reference signal of the reference pixel unit 202 at the time point Tx2, and provide the sensing signal and the reference signal to the correction circuit 212, so that the correction circuit 212 performs subtraction on the sensing signal and the reference signal to output the corrected pixel data. For example, after subtraction of the node voltages SN and SN′, an unattenuated sensing voltage value Vs corresponding to the image sensing result can be obtained.

In conclusion, the image sensor of the invention can store each of the pixel sensing data in an analog form through the charge storage component of each active pixel unit, and eliminate the voltage decrease condition caused by the leakage current effect of the charge storage component through the reference signal provided by the reference pixel unit, so that each active pixel unit can output available pixel data at any time point according to the data transmission request of the serial peripheral interface.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

What is claimed is:

1. An image sensor, comprising:
a signal processor; and
a pixel array, comprising:
a plurality of active pixel units, coupled to the signal processor and configured to receive an image light signal during an image sensing period to output a plurality of sensing signals; and
a plurality of reference pixel units, coupled to the signal processor, the reference pixel units being masked and not receiving the image light signal during the image sensing period, so as to output a plurality of reference signals, wherein the active pixel units and the reference pixel units are positioned in a same row, and the signal processor is configured to receive the sensing signals and the reference signals and perform subtraction on the sensing signals and the reference signals to correspondingly generate a plurality of pixel data.

2. The image sensor according to claim 1, wherein the image sensor further comprises a serial peripheral interface coupled to the signal processor, and the signal processor further comprises:
a readout circuit, coupled to the active pixel units and the reference pixel units and configured to simultaneously read out the sensing signals and the reference signals at a data readout time point; and
a correction circuit, coupled to the readout circuit and the serial peripheral interface and configured to receive the sensing signals and the reference signals, wherein the correction circuit performs subtraction on the sensing signals and the reference signals to output the pixel data to the serial peripheral interface.

3. The image sensor according to claim 2, wherein the image sensor determines, according to a data transmission request of the serial peripheral interface, whether to read out the sensing signals of the active pixel units and the reference signals of the reference pixel units in one of a plurality of columns of the pixel array.

4. The image sensor according to claim 1, wherein the active pixel units and the reference pixel units each at least comprise:
a first switch, wherein a first terminal of the first switch is coupled to a reference voltage;
a photodiode, wherein a first terminal of the photodiode is coupled to a second terminal of the first switch, and a second terminal of the photodiode is grounded;
a second switch, wherein a first terminal of the second switch is coupled to the second terminal of the first switch and the first terminal of the photodiode;
at least one charge storage component, wherein a first terminal of the charge storage component is coupled to a second terminal of the second switch, and a second terminal of the at least one charge storage component is grounded;
a third switch, wherein a first terminal of the third switch is coupled to the second terminal of the second switch and the first terminal of the at least one charge storage component, and a second terminal of the third switch is coupled to a floating diffusion node;
a fourth switch, wherein a first terminal of the fourth switch is coupled to the reference voltage, and a second terminal of the fourth switch is coupled to the floating diffusion node; and
a fifth switch, wherein a first terminal of the fifth switch is coupled to the reference voltage, a control terminal of the fifth switch is coupled to the floating diffusion node, a second terminal of the fifth switch is coupled to a data output terminal, and the data output terminal is coupled to the signal processor.

5. The image sensor according to claim 4, wherein the respective photodiodes of the active pixel units sense the image light signal during the image sensing period, and the respective photodiodes of the active pixel units output the sensing signals to the respective charge storage components of the active pixel units at a data storage time point to enable the respective charge storage components of the active pixel units to store the sensing signals,
wherein the respective photodiodes of the reference pixel units do not sense the image light signal during the image sensing period, and the respective photodiodes of the reference pixel units output the reference signals to the respective charge storage components of the reference pixel units at the data storage time point to enable the respective charge storage components of the reference pixel units to store the reference signals.

6. The image sensor according to claim 5, wherein the respective charge storage components of the active pixel units and the respective charge storage components of the reference pixel units comprise a same leakage current.

7. The image sensor according to claim 5, wherein the respective third switches and the respective fourth switches of the active pixel units and the respective third switches and the respective fourth switches of the reference pixel units are simultaneously turned on at a data readout time point, so that the signal processor simultaneously reads out the sensing signals and the reference signals of the respective charge storage components through the second terminals of the respective fifth switches of the active pixel units and the second terminals of the respective fifth switches of the reference pixel units.

8. The image sensor according to claim 1, wherein the pixel array performs a global shutter operation during the image sensing period to simultaneously expose each of the active pixel units of the pixel array.

9. The image sensor according to claim 1, wherein the pixel array performs a rolling shutter operation during the image sensing period to simultaneously expose the active pixel units in each column of the pixel array, and the columns of the pixel array are sequentially exposed.

10. The image sensor according to claim 1, wherein the image sensor is a fingerprint sensor.
